(19) United States
(12) Patent Application Publication
(10) Pub. No.: US 2025/0210458 A1
(43) Pub. Date: Jun. 26, 2025

(54) THERMAL STRUCTURE FOR SEMICONDUCTOR PACKAGE

(71) Applicant: Taiwan Semiconductor Manufacturing Co., Ltd., Hsinchu (TW)

(72) Inventors: Chien-Chang Wang, Hsinchu (TW); Kuan-Min Wang, Hsinchu (TW); Ching Wang, Taichung City (TW); Kuo-Chin Chang, Chiayi City (TW); Kathy Wei Yan, Hsinchu (TW); Jun He, Zhubei City (TW)

(21) Appl. No.: 18/600,931

(22) Filed: Mar. 11, 2024

Related U.S. Application Data
(60) Provisional application No. 63/614,696, filed on Dec. 26, 2023.

(51) Int. Cl. H01L 23/473; H01L 23/427; H01L 23/467; H10N 10/13; H10N 19/00

(52) U.S. Cl. CPC H01L 23/473; H01L 23/427; H01L 23/467; H10N 10/13; H10N 19/00

(57) ABSTRACT

A package structure includes a high-power package attached to a substrate; a first low-power package attached to the substrate; a first heat dissipation device attached to the first low-power package; a liquid cooling system attached to the high-power package; and a thermoelectric system sandwiched between the high-power package and the liquid cooling system, wherein the thermoelectric system is electrically connected to the first heat dissipation device, wherein the thermoelectric system provides the first heat dissipation device with electrical power during operation of the high-power package.

### PRIORITY CLAIM AND CROSS-REFERENCE

This application claims the benefit of U.S. Provisional Application No. 63/614,696, filed on Dec. 26, 2023, which application is hereby incorporated herein by reference.

### BACKGROUND

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed. For example, one problem of concern is the dissipation of heat.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a thermoelectric generator (TEG), in accordance with some embodiments.

FIGS. 2 and 3 schematically illustrate an electronic device with thermal management components, in accordance with some embodiments.

FIGS. 4A, 4B, and 4C schematically illustrate TEG systems, in accordance with some embodiments.

FIG. 5 schematically illustrates an electronic device with thermal management components and a power source, in accordance with some embodiments.

FIG. 6 schematically illustrates an electronic device with thermal management components including a thermal interface structure, in accordance with some embodiments.

FIG. 7 schematically illustrates an electronic device with thermal management components including a heat pipe, in accordance with some embodiments.

FIG. 8 schematically illustrates an electronic device with thermal management components, in accordance with some embodiments.

FIG. 9 schematically illustrates an electronic device with thermal management components including a power generator, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments of the present disclosure, thermoelectric generators (TEGs) are utilized to generate electrical power from the waste heat of high-power packages of a computing system. The electrical power is utilized to power heat dissipation devices, such as cooling fans, of low-power packages of the same computing system. In other words, electrical power generated from the heat dissipation of high-power packages is utilized to facilitate the heat dissipation of low-power packages. In this manner, the energy used for heat dissipation within a computing system may be reduced. Structures such as vapor chambers, heat pipes, heat spreaders, liquid cooling systems, or the like may be combined with the TEGs to provide more efficient and uniform electrical power generation.

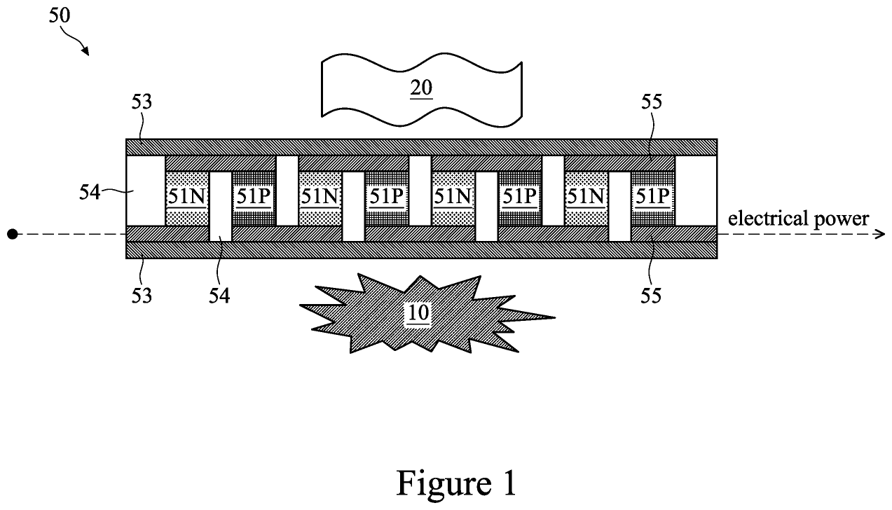

FIG. 1 illustrates a schematic cross-sectional view of a thermoelectric generator (TEG) 50, in accordance with some embodiments. The TEG 50 may be considered a thermoelectric generator unit, thermoelectric generator module, thermoelectric component, or the like. The TEG 50 utilizes a heat difference between opposite sides of itself to generate electrical power. For example, as schematically shown in FIG. 1, the TEG 50 is between a relatively hot region 10 and a relatively cool region 20. The heat difference between the relatively hot region 10 and the relatively cool region 20 allows the TEG 50 to create a voltage potential, which can be harnessed a source of electrical power. Accordingly, a TEG 50 may be connected to or include appropriate circuitry or wiring to provide the electrical power output of the TEG 50 in a suitable form. In some cases, multiple TEGs 50 may be connected in series and/or in parallel, for example, to provide greater overall electrical power output. The TEG 50 shown in FIG. 1 is intended as an example, and the TEGs 50 used in any of the embodiments herein may be different from the TEGs 50 illustrated in the figures. Accordingly, all suitable variations of TEGs 50 are within the scope of the present disclosure.

Still referring to FIG. 1, the TEG 50 comprises alternating regions of an n-type material 51N and a p-type material 51P, in some embodiments. The materials 51N and 51P may comprise the same material, with the material 51N doped by n-type dopants and the material 51P doped by p-type dopants. For example, the materials 51N and 51P may both comprise doped bismuth telluride, though other materials are possible. In other cases, the materials 51N and 51P may comprise different materials or different combinations of materials. Neighboring regions of materials 51N and 51P may be electrically insulated by an insulating material 54. The insulating material 54 may comprise a dielectric material, a ceramic material, or the like. The alternating regions of material 51N and 51P may be electrically connected in a serial configuration by conductive interconnects 55, which may comprise metal layers or the like. The serially-connected regions of material 51N and 51P may be arranged in one or more linear rows, may be arranged in a serpentine pattern over an area, or may have any other suitable arrangement. The TEG 50 may have an insulating layer 53 on the top side and/or bottom side to protect and insulate the conductive interconnects 55 and the regions of material 51N and 50P. The insulating layer 53 may comprise a suitable material, such as a dielectric or ceramic material, or the like. The material of the insulating layer 53 may be similar to or different than the insulating material 54. This is an example, and other TEGs 50 are possible.

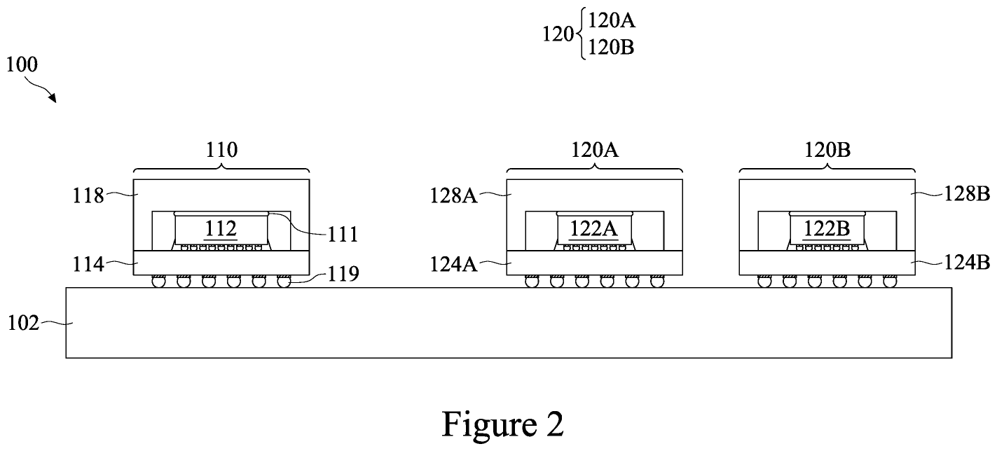

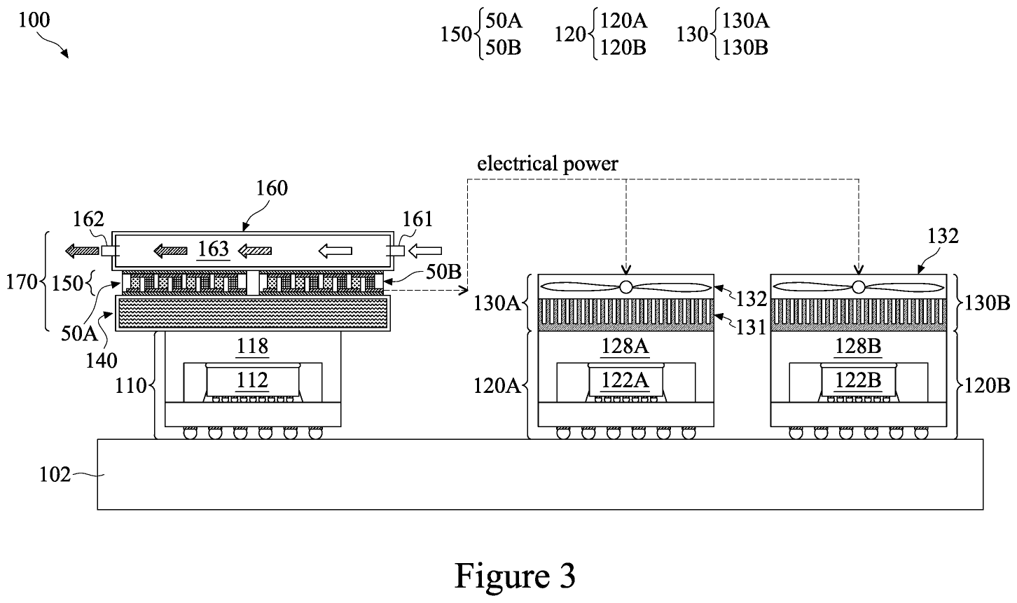

FIGS. 2 and 3 illustrate schematic cross-sectional views of an electronic device 100, in accordance with some embodiments. The electronic device 100 may be, for example, a computing system, a package, a package structure, or the like. FIG. 2 illustrates a high-power package 110 and low-power packages 120 attached to a substrate 102, and FIG. 3 additionally schematically illustrates thermal management components of the electronic device 100, described in greater detail below. The electronic device 100, high-power package 110, low-power packages 120, and thermal management components are intended as examples, and other arrangements, numbers, configurations, or variations are within the scope of the present disclosure.

The substrate 102 may be any suitable substrate or component, such as a device die, a redistribution structure, an interposer, a wafer, an organic core substrate, a printed circuit board (PCB), a motherboard, a main board, or the like. The substrate 102 may or may not comprise active devices and/or passive devices. The substrate 102 may comprise conductive features such as conductive lines, vias, or pads to make electrical interconnections within the substrate 102 and to make electrical connections to external packages or external components attached to the substrate 102.

FIG. 2 illustrates a single high-power package 110 attached to the substrate 102 and multiple low-power packages 120 attached to the substrate 102, in accordance with some embodiments. In other embodiments, more than one high-power package 110 may be present. The embodiments herein are illustrated as having two low-power packages 120 attached to the substrate 102, designated as low-power packages 120A and 120B, but in other embodiments more or fewer low-power packages 120 may be present. The low-power package 120A may be similar to or different from the low-power package 120B. In some cases, a high-power package 110 or a low-power package 120 may be a chip-on-wafer-on-substrate (CoWoS) package, although other types of packages are possible.

In some embodiments, the high-power package 110 may be a package or component suitable for relatively higher power applications, such as a package or component rated for greater than about 1000 Watts. High-power packages 110 such as these can generate significant excess heat during operation, and thermal management components may be used to dissipate this excess heat. In some embodiments, the low-power packages 120 may be packages or components suitable for relatively lower power applications, such as packages or components rated for less than about 1000 Watts. Accordingly, a low-power package 120 may generate less excess heat during operation than a high-power package 110. In some cases, simpler, cheaper, or less efficient thermal management components may be used for a low-power package 120 than for a high-power package 110. Other power ratings, power characteristics, or thermal characteristics are possible.

In some embodiments, the high-power package 110 comprises one or more package components 112 attached to a package substrate 114. A package component 112 may comprise a semiconductor device, an integrated circuit die, a chip, a module, or the like. The package component 112 may comprise a logic die (e.g., central processing unit (CPU, xPU), graphics processing unit (GPU), system-on-a-chip (SoC), application processor (AP), microcontroller, etc.), a memory die (e.g., dynamic random access memory (DRAM) die, static random access memory (SRAM) die, a hybrid memory cube (HMC) die, a high bandwidth memory (HBM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), a BaseBand (BB) die, the like, or combinations thereof.

The package substrate 114 may be any suitable substrate, such as a device die, a redistribution structure, an interposer, a wafer, an organic core substrate, a printed circuit board (PCB), or the like. The package substrate 114 may or may not comprise active devices and/or passive devices. The package substrate 114 may comprise conductive features such as conductive lines, conductive vias, conductive pads, or the like.

The package substrate 114 may be attached to the substrate 102 using conductive connectors 119, such as ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors may include a conductive material such as solder, copper, aluminum, gold, nickel, silver, palladium, tin, the like, or a combination thereof. In some embodiments, the conductive connectors are formed by initially forming a layer of solder through evaporation, electroplating, printing, solder transfer, ball placement, or the like. Once a layer of solder has been formed, a reflow may be performed in order to shape the material into the desired bump shapes. In another embodiment, the conductive connectors include metal pillars (such as copper pillars) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

The package component 112 may be attached to the package substrate 114 using conductive connectors, which may be similar to those described above for the conductive connectors 119. In other cases, the package component 112 is attached to the package substrate 114 using fusion bonding, such as dielectric-to-dielectric bonding and/or metal-to-metal bonding In some cases, and underfill or the like may be present between the package component 112 and the package substrate 114.

The high-power package 110 may also include a lid 118, in some cases. The lid 118 may be formed of a thermally conductive material, such as a metal, to facilitate heat dissipation of the package component 112. The lid 118 may be attached to the package substrate 114 using an adhesive or the like. A thermal interface material (TIM) 111 or the like may be present between the package component 112 and the lid 118 to facilitate transfer of heat from the package component 112 to the lid 118. In some cases, the lid 118 may comprise a heat spreader or may function as a heat spreader.

In some embodiments, a low-power package 120A/120B comprises one or more package components 122A/122B attached to a package substrate 124A/124B. A lid 128A/128B may be attached to the package substrate 124A/124B, and a TIM may be present between the package component 122A/122B and the lid 128A/128B. The package components 122A-B and package substrates 124A-B may be similar to the package component 112 or package substrate 114 described previously, in some cases. The low-power package 120A may be similar to or different from the low-power package 120B. Another number of lower-power packages 120 may be present.

In FIG. 3, thermal management components of the electronic device 100 are shown attached to the high-power package 110 and the low-power packages 120A-B, in accordance with some embodiments. The thermal management components for the electronic device 100 comprise thermal management components 170 for the high-power package 110 and thermal management components 130A-B for the low-power packages 120A-B. The thermal management components 170 for the high-power package 110 comprise a vapor chamber 140, a TEG system 150, and a liquid cooling system 160. In some embodiment, the TEG system 150 is sandwiched between the vapor chamber 140 and the liquid cooling system 160. The TEG system 150 comprises one or more TEGs 50 (e.g., 50A-B) that generate electrical power, similar to the example TEG 50 described above for FIG. 1. The thermal management components 130A/130B for the low-power package 120A/120B each comprise a powered heat dissipation component 132, such as a cooling fan, liquid cooling system, or the like. As described in greater detail below, the TEG system 150 may be utilized to provide power for the thermal management components 130A-B, improving the overall efficiency of thermal management for the electronic device 100. The thermal management components 170 and 130A-B are schematically illustrated for explanatory purposes, and may have other configurations, dimensions, arrangements, or features than shown.

The vapor chamber 140 is attached to the lid 118 by bonding, an adhesive, or the like. The vapor chamber 140 acts to distribute heat from the lid 118 (e.g., from the package component 112) over a larger area. Accordingly, a length or area of the vapor chamber 140 may be greater than a length or area of the lid 118, as shown in FIG. 3. In other embodiments, a length or area of the vapor chamber 140 may be about the same as or smaller than a length or area of the lid 118. The vapor chamber 140 increases the heat transfer area for the high-power package 110, and thus can allow for the overlying TEG system 150 to have a larger area. Accordingly, the use of a vapor chamber 140 allows for the use of a TEG system 150 having more TEGs 50, which can increase the efficiency of electrical power generation and the amount of generated electrical power. Additionally, the vapor chamber 40 may more uniformly distribute the heat of the high-power package 110 across the TEGs 50, allowing each TEG 50 of the TEG system 150 to have similar performance (e.g., similar output).

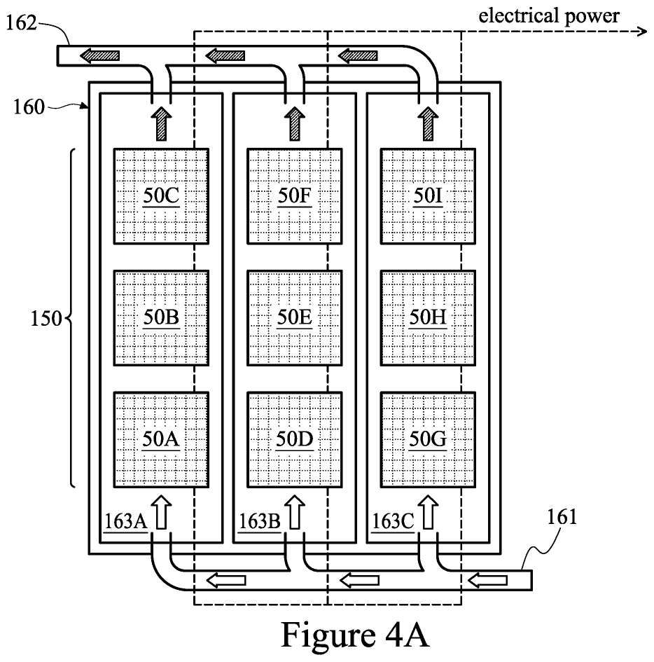

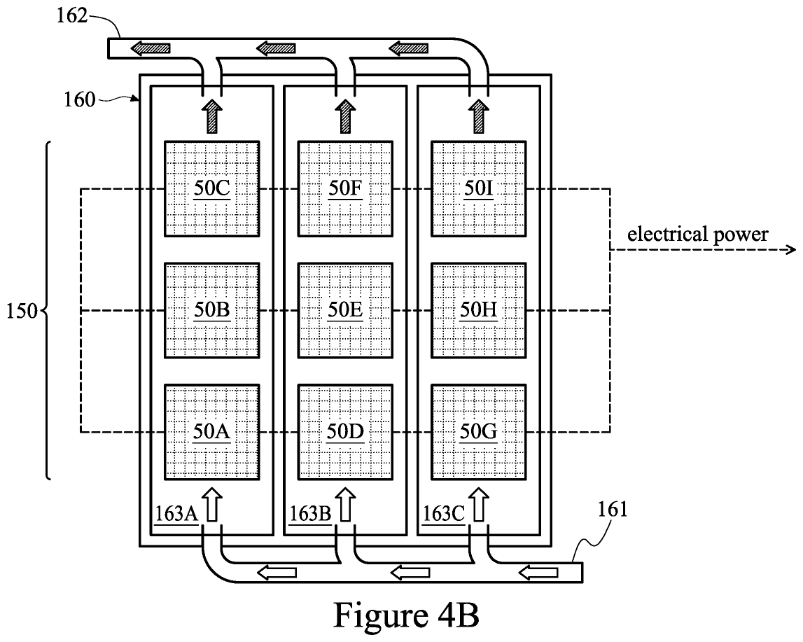

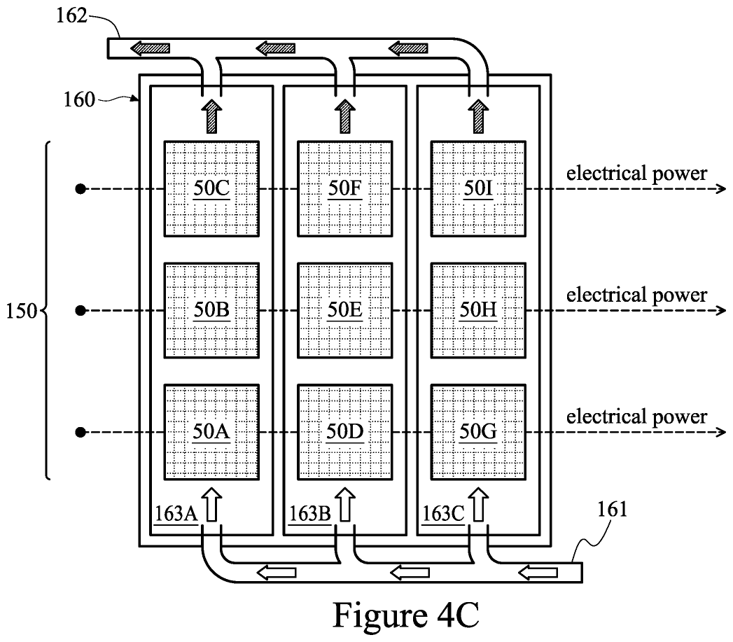

The TEG system 150 is attached to the vapor chamber 140 using bonding, an adhesive, or the like. The TEG system 150 comprises one or more TEGs 50 that generate electrical power from the heat difference between the underlying vapor chamber 140 and the overlying liquid cooling system 160. The TEG system 150 also allows for the dissipation of heat from the vapor chamber 140 to the liquid cooling system 160 as part of the thermal management of the high-power package 110. The TEGs 50 may be similar to the TEG 50 described for FIG. 1, for example. FIG. 3 shows two TEGs 50A-B of a TEG system 150, but in other embodiments a TEG system 150 may have a single TEG 50 or more than two TEGs 50. The TEGs 50 of the TEG system 150 may be electrically coupled in any suitable configuration (e.g., serially, in parallel, a combination thereof, etc.), and FIGS. 4A-4C illustrate some non-limiting examples, described in greater detail below. The TEGs 50 may also be arranged within the TEG system 150 in any suitable arrangement.

The liquid cooling system 160 comprises a liquid chamber 163, an inlet 161, and an outlet 162. The liquid chamber 163 is attached to the TEG system 150 using bonding, an adhesive, or the like. Liquid is flowed into the liquid chamber 163 from the inlet 161 and flows out of the liquid chamber 163 through the outlet 162. The liquid absorbs heat generated by the high-power package 110 and transports it away from the high-power package 110. The liquid cooling system 160 may comprise multiple chambers 163 in some cases. The liquid cooling system 160 may also comprise fins, heat sinks, or other features (not pictured) that can facilitate heat transfer. In some embodiments, the liquid flow speed of the liquid may be controlled, which may control the amount of heat dissipation provided by the liquid cooling system 160.

In some embodiments, the thermal management components 130A-B for the low-power packages 120A-B comprise heat dissipation components 132 that operate when powered by electricity. For example, FIG. 3 illustrates the heat dissipation components 132 as being cooling fans. Other heat dissipation components 132 may be used instead of or in addition to cooling fans, in other embodiments. The thermal management components 130A-B are also shown comprising heat sinks 131 that are attached to the lids 128A-B of the low-power packages 120A-B. In other embodiments, the heat sinks 131 are not present. Other thermal components such as heat spreaders, vapor chambers, or the like make be used in addition to or instead of the heat sinks 131.

As shown in FIG. 3, the TEG system 150 of the thermal management components 170 is electrically coupled (e.g., by wires or the like) to the heat dissipation components 132 of the thermal components 130A-B. Electrical power generated by the TEG system 150 is provided to the heat dissipation components 132. In other words, the TEG system 150 is able to capture waste heat from the high-power package 110 and generate electricity that powers the heat dissipation components 132. Because the low-power packages 120A-B do not generate as much heat on average as the high-power package 110, the energy needed to dissipate heat from the low-power packages 120A-B may be less than the energy needed to dissipate heat from the high-power package 110. By utilizing the heat generated by the high-power package 110 to dissipate heat from the low-power packages 120A-B as described herein, energy consumption and cost for thermal management of an electronic device may be reduced. The electronic device 100 shown in FIG. 3 is an example, and in other embodiments any suitable number of TEG systems 150 may power any suitable number of heat dissipation components 132.

The TEGs 50 of a TEG system 150 may be electrically coupled using any suitable configuration. A TEG system 150 may have TEGs 50 that are connected serially, connected in parallel, connected independently, a combination thereof, or the like. As examples, FIGS. 4A-4C illustrate schematic plan views of various TEG systems 150 and liquid cooling systems 160, in accordance with some embodiments. Both TEG systems 150 and liquid cooling systems 160 are shown schematically in FIGS. 4A-4C, even though a liquid cooling system 160 may cover a TEG system 150. The TEG systems 150 shown in FIGS. 4A-4C comprise TEGs 50A-I that generate electrical power for heat dissipation components 132 (not shown). The embodiments shown in FIGS. 4A, 4B, and 4C are similar other than the electrical connections between the TEGs 50A-I of the TEG system 150. The TEG systems 150 shown in FIGS. 4A-4C are intended as non-limiting examples, and in other embodiments, the locations, arrangement, dimensions, and number of TEGs 50 within a TEG system 150 may be different than shown. Any suitable variations are within the scope of the present disclosure, and may depend on the specific application.

In FIGS. 4A-4C, the liquid cooling system 160 is shown as comprising multiple liquid chambers 163A-C. Each liquid chamber 163A-C is independently connected to the inlet 161 and the outlet 162, such that liquid flows through each liquid chamber 163A-C. Accordingly, the liquid chambers 163A-C may be considered channels or the like in some cases. FIGS. 4A-4C show three liquid chambers 163A-C, but more or fewer liquid chambers 163 may be present. In some cases, fins or other heat dissipation features may be present within or on the liquid chambers 163A-C. In some embodiments, the TEGs 50 of the TEG system 150 may be arranged along the liquid chambers 163. For example, in FIGS. 4A-4C, TEGs 50A-C are located along liquid chamber 163A, TEGs 50D-F are located along liquid chamber 163B, and TEGs 50G-I are located along liquid chamber 163C. Locating the TEGs 50 along liquid chambers 163 can allow for improved heat dissipation and more efficient electrical power generation. Additionally, the TEGs 50 may be electrically connected to provide more uniform electrical power generation, described in greater detail below.

In FIG. 4A, the TEGs 50A-I are configured in parallel connections along each liquid chamber 163A-C. For example, a first parallel connection comprises TEGs 50A-C connected in series, a second parallel connection comprises TEGs 50D-F connected in series, and a third parallel connection comprises TEGs 50G-I connected in series. Each parallel connection is arranged along a corresponding liquid chamber 163A-C. For example, the serially-connected TEGs 50 of each parallel connection are arranged in the direction of liquid flow within the corresponding liquid chamber 163. Arranging the TEGs 50 in parallel connections along liquid chambers 163 can result in each parallel connection having a similar electrical power output, which can improve uniformity and reliability. Other variations are possible, such as more than one parallel connection being arranged along the same liquid chamber. All such variations are within the scope of the present disclosure.

In FIG. 4B, the TEGs 50A-I are configured in parallel connections across the liquid chambers 163A-C. For example, a first parallel connection comprises TEGs 50A, 50D, and 50F connected in series, a second parallel connection comprises TEGs 50B, 50E, and 50H connected in series, and a third parallel connection comprises TEGs 50C, 50F, and 50I connected in series. Each parallel connection comprises TEGs 50 ovalonger each of the liquid chambers 163A-C. In some cases, the parallel connections of TEGs 50 as shown in FIG. 4B may allow for more uniform power generation. Other variations are possible.

In FIG. 4C, the TEGs 50A-I are configured in independent connections across the liquid chambers 163A-C. For example, a first independent connection comprises TEGs 50A, 50D, and 50G connected in series, a second independent connection comprises TEGs 50B, 50E, and 50H connected in series, and a third independent connection comprises TEGs 50C, 50F, and 50I connected in series. Each independent connection comprises TEGs 50 along each of the liquid chambers 163A-C. In some cases, the independent connections of TEGs 50 as shown in FIG. 4C may allow for redundancy, reducing the possibility of insufficient power for driving the heat dissipation components 132. Other variations are possible, such as an independent connection comprising TEGs 50 located along the same liquid chamber 163, or each independent connection comprising multiple parallel connections. All such variations are within the scope of the present disclosure.

In some embodiments, the power output (e.g., voltage and/or current) of the TEG system 150 may be monitored, and the operation of the liquid cooling system 160 adjusted based on the power output. For example, the flow speed of the liquid in the liquid cooling system 160 may be increased to increase the heat difference across the TEG system 150, which increases the output power of the TEG system 150. Similarly, the flow speed may be decreased to decrease the output power of the TEG system 150. In some embodiments, the TEG system 150 comprises variable resistor(s) that may be controlled to control the output power of the TEG system 150. A variable resistor may be serially connected at the output of the TEG system 150, for example, to increase or decrease the overall output power of the TEG system 150. In such embodiments, increasing the resistance of the variable resistor decreases the overall output power of the TEG system 150, and decreasing the resistance variable resistor increases the overall output power of the TEG system 150. In some embodiments, a variable resistor may be present at the output of each parallel or independent connection. The variable resistors may be independently controlled to control the output power of each parallel or independent connection, in some embodiments. In this manner, the output power of each parallel or independent connection may be controlled, for example, to provide more uniform overall output power or to compensate for local variations of heat dissipation. In some embodiments, the output power of the TEG system 150 may be controlled as described above to provide a constant output power or to provide a desired output power, for example. The output power of the TEG system 150 may be controlled according to the electrical requirements or thermal conditions of the heat dissipation components 132. Additionally, the output power of the TEG system 150 may be controlled to keep the output power of the TEG system 150 within a desired range. The output power of the TEG system 150 may be controlled to provide other benefits not described here.

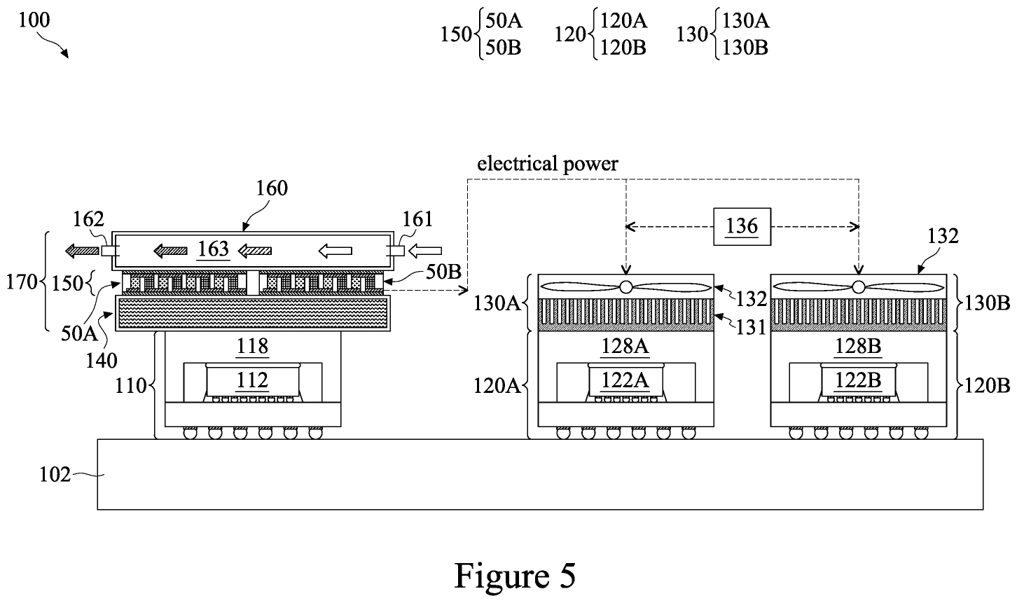

FIG. 5 illustrates an electronic device 100 with a power source 136 connected to heat dissipation components 132, in accordance with some embodiments. The electronic device 100 of FIG. 5 is similar to that of FIG. 3, except that a power source 136 is electrically connected to the heat dissipation components 132. The power source 136 is electrically connected to the heat dissipation components 132 of the thermal management components 130A-B to provide additional power to the heat dissipation components 132. For example, if the electrical power generated by the TEG system 150 is insufficient, additional electrical power may be supplied by the power source 136. A single power source 136 may be connected to multiple heat dissipation components 132, as shown in FIG. 5. The power source 136 may be an external power supply or may be an internal power supply such as a battery, capacitor, or the like. In other embodiments multiple power sources 136 may be present, with each heat dissipation component 132 connected to a separate power source 136. One or more power sources 136 may be utilized in any of the embodiments described herein.

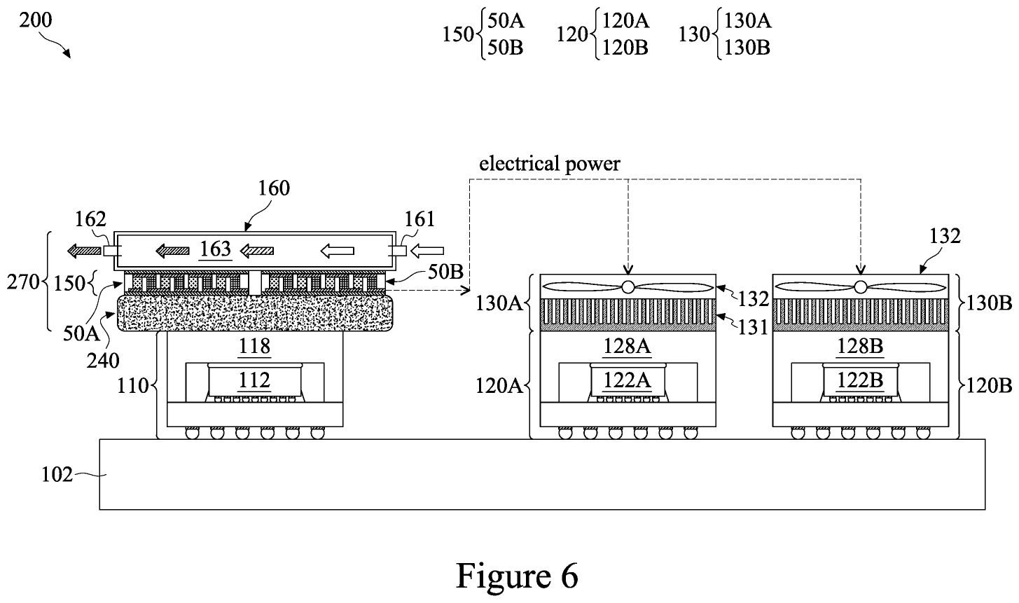

FIG. 6 illustrates an electronic device 200 with thermal management components 270 for a high-power package 110, in accordance with some embodiments. The electronic device 200 of FIG. 6 is similar to the electronic device 100 of FIG. 3, except that the thermal management components 270 for the high-power package 110 use a thermal interface structure 240 instead of a vapor chamber 140. The thermal interface structure 240 extends between the high-power package 110 and the TEG system 150, and may be attached to the lid 118 by bonding, adhesion, or the like. The thermal interface structure 240 may have a larger area than the high-power package 110 to allow for a larger TEG system 150, similar to the vapor chamber 140 of FIG. 3. Accordingly, the thermal interface structure 240 may be considered a heat spreader in some cases. In some embodiments, the thermal interface structure 240 comprises a thermal interface material (TIM) or the like. In some embodiments, the thermal interface structure 240 comprises a metal or other substantially rigid material that is thermally conductive. The thermal interface structure 240 may be a material similar to that of the lid 118, in some cases.

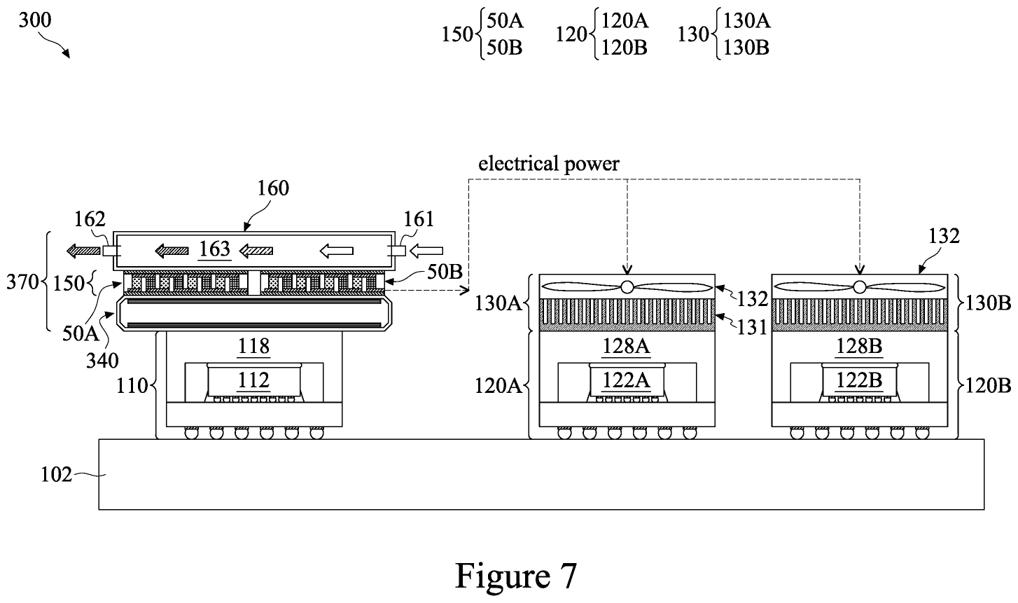

FIG. 7 illustrates an electronic device 300 with thermal management components 370 for a high-power package 110, in accordance with some embodiments. The electronic device 300 of FIG. 7 is similar to the electronic device 100 of FIG. 3, except that the thermal management components 370 for the high-power package 110 use one or more heat pipes 340 instead of a vapor chamber 140. The heat pipes 340 extend between the high-power package 110 and the TEG system 150, and may be attached to the lid 118 by bonding, adhesion, or the like. The heat pipes 340 may have a larger area than the high-power package 110 to allow for a larger TEG system 150. In some embodiments, the TEGs 50 (e.g., 50A-B) of the TEG system 150 are located along the one or more heat pipes 340 to facilitate efficient heat transfer. In some embodiments, parallel connections of TEGs 50 may be located along or across multiple heat pipes 340, similar to the arrangement of TEGs 50 along multiple liquid chambers 163 described previously for FIGS. 4A-4C.

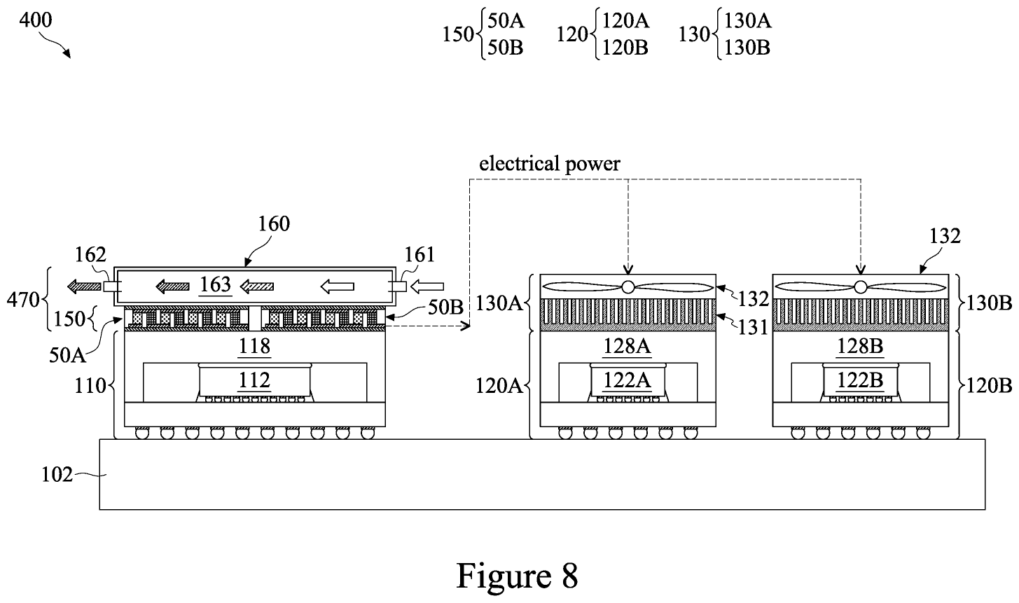

FIG. 8 illustrates an electronic device 400 with thermal management components 470 for a high-power package 110, in accordance with some embodiments. The electronic device 400 of FIG. 8 is similar to the electronic device 100 of FIG. 3, except that the thermal management components 470 for the high-power package 110 do not include a vapor chamber 140. In FIG. 8, the TEG system 150 is directly attached to the lid 118 by bonding, adhesion, or the like. In some cases, the TEG system 150 may be directly attached to the lid 118 for high-power packages 110 that have a large enough area to accommodate the area of the TEG system 150. In such cases, the TEG system 150 may have an area that is about the same as or less than an area of the lid 118. In the embodiment of FIG. 8, the lid 118 may act as a heat spreader to distribute the heat from the package component 112 across the TEG system 150. By omitting the vapor chamber 140, the heat transfer efficiency between the high-power package 110 and the TEG system 115 may be improved, in some cases.

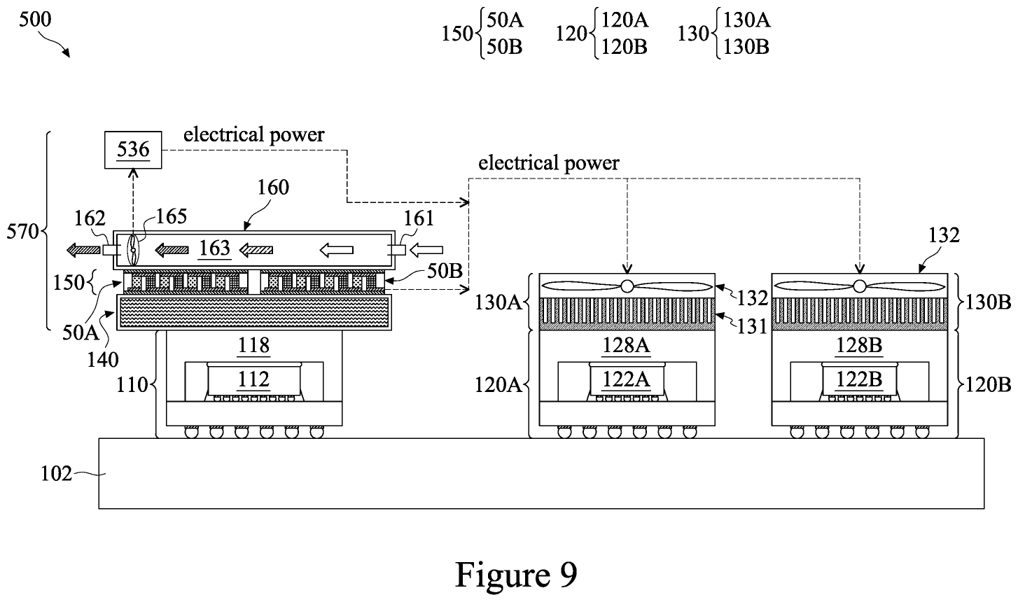

FIG. 9 illustrates an electronic device 500 with thermal management components 570 for a high-power package 110, in accordance with some embodiments. The electronic device 500 of FIG. 9 is similar to the electronic device 100 of FIG. 3, except that the thermal management components 570 for the high-power package 110 includes a power generator 536 that can provide additional electrical power to the heat dissipation components 132. In some embodiments, the liquid cooling system 160 may comprise one or more rotors 165 that are rotated by the cooling liquid as it flows through the one or more liquid chambers 163 of the liquid cooling system 160. The mechanical action of the rotor(s) 165 may be used to generate electrical power, which is output by the power generator 536. In some embodiments, electrical power is generated by the rotor(s) 165, and the rotors(s) 165 provide the electrical power to the power generator 536 for output. In other embodiments, the rotation of the rotor(s) 165 is mechanically coupled into the power generator 536 (e.g., using a belt or the like), and the power generator 536 generates electrical power from the coupled mechanical action.

The power generator 536 is electrically connected to the heat dissipation components 132 and can provide electrical power to the heat dissipation components 132. The electrical power from the power generator 536 may be used instead of or in addition to the electrical power provided by the TEG system 150. In this manner, the energy consumption and cost of thermal management for the electronic device 500 may be reduced. In other embodiments, the power generator 536 and the TEG system 150 may be connected to different heat dissipation components 132. In some embodiments, the flow of the liquid within the liquid cooling system 160 may be controlled to control the amount of electrical power generated and provided by the rotor(s) 165 and power generator 536. Controlling the liquid flow may also control the amount of electrical power generated by the TEG system 150, in some cases.

The embodiments described herein may achieve advantages. In some cases, computing systems or other electronic devices may have multiple packages with different power consumptions and which generate different amounts of heat. Embodiments herein describe the use of thermoelectric generators (TEG) to generate electrical power from waste heat captured from high-power packages, and to utilize that electrical power to drive the thermal management components (e.g., cooling fans) of low-power packages. Thus, waste heat can be converted to electricity within the same system, which can reduce the external power needed, reduce cost, and improve the efficiency of the thermal management of the system. TEGs are both scalable and durable, and can be arranged and connected flexibly into TEG systems that are application-specific. The amount of electrical power generated by the TEGs can be controlled to provide efficient heat dissipation for both the high-power packages and the low-power packages. Additional structures like vapor chambers, heat pipes, thermal interface materials (TIMs), or the like may be present between a high-power package and a TEG system to allow for larger TEG systems and to allow for more even heat distribution.

In some embodiments of the present disclosure, a package structure includes a high-power package attached to a substrate; a first low-power package attached to the substrate; a first heat dissipation device attached to the first low-power package; a liquid cooling system attached to the high-power package; and a thermoelectric system sandwiched between the high-power package and the liquid cooling system, wherein the thermoelectric system is electrically connected to the first heat dissipation device, wherein the thermoelectric system provides the first heat dissipation device with electrical power during operation of the high-power package. In an embodiment, the package structure includes a vapor chamber sandwiched between the high-power package and the thermoelectric system. In an embodiment, the first heat dissipation device is a cooling fan. In an embodiment, the package structure includes a power generator, wherein the power generator provides the first heat dissipation device with electrical power during operation of the liquid cooling system. In an embodiment, the package structure includes a second heat dissipation device attached to a second low-power package, wherein the thermoelectric system is electrically connected to the second heat dissipation device, wherein the thermoelectric system provides the second heat dissipation device with electrical power during operation of the high-power package. In an embodiment, the thermoelectric system includes multiple thermoelectric generators. In an embodiment, the thermoelectric generators are electrically connected in multiple parallel connections, wherein each parallel connection includes a set of thermoelectric generators connected in a series. In an embodiment, each set of serially-connected thermoelectric generators is arranged along a direction of liquid flow within the liquid cooling system.

In some embodiments of the present disclosure, a device includes a first semiconductor die; a first thermal management structure attached to the first semiconductor die, wherein the first thermal management structure includes: a heat distribution structure; and a thermoelectric generator on the heat distribution structure; a second semiconductor die; and a second thermal management structure attached to the second semiconductor die, wherein the second thermal management structure includes a heat dissipation component connected to the thermoelectric generator, wherein the heat dissipation component is configured to receive electrical power from the thermoelectric generator. In an embodiment, power consumption of the first semiconductor die during operation is greater than 1000 Watts. In an embodiment, the first semiconductor die and the second semiconductor die are attached to the same package substrate. In an embodiment, the first thermal management structure includes a liquid cooling system on the thermoelectric generator. In an embodiment, the heat distribution structure includes a heat pipe. In an embodiment, the device includes a lid between the first semiconductor die and the heat distribution structure. In an embodiment, the area of the heat distribution structure is greater than the area of the lid. In an embodiment, the second thermal management structure includes a heat sink.

In some embodiments of the present disclosure, a method includes operating a first semiconductor package, wherein the first semiconductor package generates heat; generating electrical power using a thermoelectric generator attached to the first semiconductor package, wherein the thermoelectric generator generates the electrical power based on the heat generated by the first semiconductor package; transmitting the electrical power generated by the thermoelectric generator to a heat dissipation device attached to a second semiconductor package; and cooling the second semiconductor package using the heat dissipation device. In an embodiment, the method includes controlling the electrical power generated by the thermoelectric generator by controlling a liquid flow speed of a liquid cooling system that is attached to the thermoelectric generator. In an embodiment, the method includes controlling the electrical power generated by the thermoelectric generator by controlling a resistance of a variable resistor that is electrically coupled to the thermoelectric generator. In an embodiment, the method includes transmitting electrical power from an external power source to the heat dissipation device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a high-power package attached to a substrate;
a first low-power package attached to the substrate;
a first heat dissipation device attached to the first low-power package;
a liquid cooling system attached to the high-power package; and
a thermoelectric system sandwiched between the high-power package and the liquid cooling system, wherein the thermoelectric system is electrically connected to the first heat dissipation device, wherein the thermoelectric system provides the first heat dissipation device with electrical power during operation of the high-power package.

2. The package structure of claim 1 further comprising a vapor chamber sandwiched between the high-power package and the thermoelectric system.

3. The package structure of claim 1, wherein the first heat dissipation device is a cooling fan.

4. The package structure of claim 1 further comprising a power generator, wherein the power generator provides the first heat dissipation device with electrical power during operation of the liquid cooling system.

5. The package structure of claim 1 further comprising a second heat dissipation device attached to a second low-power package, wherein the thermoelectric system is electrically connected to the second heat dissipation device, wherein the thermoelectric system provides the second heat dissipation device with electrical power during operation of the high-power package.

6. The package structure of claim 1, wherein the thermoelectric system comprises plurality of thermoelectric generators.

7. The package structure of claim 6, wherein the thermoelectric generators are electrically connected in a plurality of parallel connections, wherein each parallel connection comprises a set of thermoelectric generators connected in a series.

8. The package structure of claim 7, wherein each set of serially-connected thermoelectric generators is arranged along a direction of liquid flow within the liquid cooling system.

9. A device, comprising:
a first semiconductor die;
a first thermal management structure attached to the first semiconductor die, wherein the first thermal management structure comprises:
a heat distribution structure; and
a thermoelectric generator on the heat distribution structure;
a second semiconductor die; and
a second thermal management structure attached to the second semiconductor die, wherein the second thermal management structure comprises a heat dissipation component connected to the thermoelectric generator, wherein the heat dissipation component is configured to receive electrical power from the thermoelectric generator.

10. The device of claim 9, wherein power consumption of the first semiconductor die during operation is greater than 1000 Watts.

11. The device of claim 9, wherein the first semiconductor die and the second semiconductor die are attached to the same package substrate.

12. The device of claim 9, wherein the first thermal management structure further comprises a liquid cooling system on the thermoelectric generator.

13. The device of claim 9, wherein the heat distribution structure comprises a heat pipe.

14. The device of claim 9 further comprising a lid between the first semiconductor die and the heat distribution structure.

15. The device of claim 14, wherein the area of the heat distribution structure is greater than the area of the lid.

16. The device of claim 9, wherein the second thermal management structure further comprises a heat sink.

17. A method comprising:
operating a first semiconductor package, wherein the first semiconductor package generates heat;
generating electrical power using a thermoelectric generator attached to the first semiconductor package, wherein the thermoelectric generator generates the electrical power based on the heat generated by the first semiconductor package;
transmitting the electrical power generated by the thermoelectric generator to a heat dissipation device attached to a second semiconductor package; and
cooling the second semiconductor package using the heat dissipation device.

18. The method of claim 17 further comprising controlling the electrical power generated by the thermoelectric generator by controlling a liquid flow speed of a liquid cooling system that is attached to the thermoelectric generator.

19. The method of claim 17 further comprising controlling the electrical power generated by the thermoelectric generator by controlling a resistance of a variable resistor that is electrically coupled to the thermoelectric generator.

20. The method of claim 17 further comprising transmitting electrical power from an external power source to the heat dissipation device.
